(19) United States
(12) Patent Application Publication
(10) Pub. No.: US 2024/0142875 A1
(43) Pub. Date: May 2, 2024

(54) NEGATIVE TYPE PHOTOSENSITIVE COMPOSITION

(71) Applicant: Merck Patent GmbH, Darmstadt (DE)

(72) Inventors: Akira YAMASAKI, Kakegawa-Shi (JP); Atsuko NOYA, Kakegawa-Shi (JP)

(21) Appl. No.: 18/269,074

(22) PCT Filed: Dec. 22, 2021
(86) PCT No.: PCT/EP2021/087183

§ 371 Date: Jun. 22, 2023

(30) Foreign Application Priority Data
Dec. 25, 2020 (JP) 2020-216910

(51) Int. Cl. G03F 7/075; G03F 7/40

(52) U.S. Cl. CPC G03F 7/0757; G03F 7/40

(57) ABSTRACT

[Problem] To provide a negative type photosensitive composition capable of forming a cured film having a certain taper angle and a high transmittance. [Means for Solution] A negative type photosensitive composition comprising (I) a polysiloxane, (II) an acrylic polymer, (III) a compound containing two or more (a) (meth)acryloyloxy groups, (IV) a polymerization initiator, and (V) a solvent, wherein the component (III) is a combination of two or more kinds, and the content of the component (III) is 10.0 to 25.0 mass % based on the total mass of the component (I) and the component (II).

### BACKGROUND OF THE INVENTION

### Technical Field

The present invention relates to a negative type photosensitive composition. Further, the present invention relates to a method for manufacturing a pattern using the same, and a method for manufacturing a device using the same.

### Background Art

In display devices such as an organic electroluminescence devices (OLED), quantum dot displays, and thin film transistor arrays, partition walls are formed in order to divide between the pixels. These partition walls are generally formed by photolithography using photosensitive resin compositions.

When patterns for partition walls are formed using photosensitive resin compositions, the walls of the formed patterns are required to have taper angle according to certain needs. Methods for adjusting the taper angle by processes such as exposure amount, developing time, and post-baking temperature are known (for example, Patent Document 1).

It have been studied that the partition walls having translucency increase apparent aperture ratio, and thus increase luminance. Thus, partition walls with high transmittance are required. In this case, the materials adjacent to the partition walls can be UV cured, thereby improving the manufacturing process.

### PRIOR ART DOCUMENTS

### Patent Documents

[Patent Document 1] JP 2016-167447 A

### SUMMARY OF THE INVENTION

### Problems to be Solved by the Invention

The present invention has been made in view of the above circumstances, and its object is to provide a negative type photosensitive composition capable of forming a cured film having a certain taper angle and high transmittance.

### Means for Solving the Problems

The negative type photosensitive composition according to the present invention comprises:
(I) a polysiloxane,
(II) an acrylic polymer,
(III) a compound containing two or more (meth)acryloyloxy groups,
(IV) a polymerization initiator, and
(V) a solvent,
wherein the component (III) is a combination of two or more kinds, and
the content of the component (III) is 10.0 to 25.0 mass % based on the total mass of the component (I) and the component (II).

The method for manufacturing a pattern according to the present invention comprises applying the above-described composition above a substrate, exposing, and developing.

The method for manufacturing a device according to the present invention comprises the above-described method for manufacturing a pattern.

### Effects of the Invention

The negative type photosensitive composition according to the present invention can form a pattern having a certain taper angle by heating. The cured film manufactured by using the negative type photosensitive composition according to the present invention has high transmittance. Further, the negative type photosensitive composition according to the present invention can form a thick film.

### BRIEF DESCRIPTION OF THE DRAWING

FIG. 1 is a conceptual diagram for explaining taper angle.

### DETAILED DESCRIPTION OF THE INVENTION

### Mode for Carrying Out the Invention

Embodiments of the present invention are described below in detail.

In the present specification, symbols, units, abbreviations, and terms have the following meanings unless otherwise specified.

In the present specification, unless otherwise specifically mentioned, the singular form includes the plural form and “one” or “that” means “at least one”. In the present specification, unless otherwise specifically mentioned, an element of a concept can be expressed by a plurality of species, and when the amount (for example, mass % or mol %) is described, it means sum of the plurality of species. “And/or” includes a combination of all elements and also includes single use of the element.

In the present specification, when a numerical range is indicated using “to” or “-”, it includes both endpoints and units thereof are common. For example, 5 to 25 mol % means 5 mol % or more and 25 mol % or less.

In the present specification, the hydrocarbon means one including carbon and hydrogen, and optionally including oxygen or nitrogen. The hydrocarbyl group means a monovalent or divalent or higher valent hydrocarbon. In the present specification, the aliphatic hydrocarbon means a linear, branched, or cyclic aliphatic hydrocarbon, and the aliphatic hydrocarbon group means a monovalent or divalent or higher valent aliphatic hydrocarbon. The aromatic hydrocarbon means a hydrocarbon comprising an aromatic ring which may optionally not only comprise an aliphatic hydrocarbon group as a substituent but also be condensed with an alicycle. The aromatic hydrocarbon group means a monovalent or divalent or higher valent aromatic hydrocarbon. Further, the aromatic ring means a hydrocarbon comprising a conjugated unsaturated ring structure, and the alicycle means a hydrocarbon having a ring structure but comprising no conjugated unsaturated ring structure.

In the present specification, the alkyl means a group obtained by removing any one hydrogen from a linear or branched, saturated hydrocarbon and includes a linear alkyl and branched alkyl, and the cycloalkyl means a group obtained by removing one hydrogen from a saturated hydrocarbon comprising a cyclic structure and optionally includes a linear or branched alkyl in the cyclic structure as a side chain.

In the present specification, the aryl means a group obtained by removing any one hydrogen from an aromatic hydrocarbon. The alkylene means a group obtained by removing any two hydrogens from a linear or branched, saturated hydrocarbon. The arylene means a hydrocarbon group obtained by removing any two hydrogens from an aromatic hydrocarbon.

In the present specification, the descriptions such as “C_{x-y}”, “Cₓ-C_{y}” and “Cₓ” mean the number of carbons in the molecule or substituent group. For example, C₁₋₆ alkyl means alkyl having 1 to 6 carbons (such as methyl, ethyl, propyl, butyl, pentyl and hexyl). Further, the fluoroalkyl as used in the present specification refers to one in which one or more hydrogen in alkyl is replaced with fluorine, and the fluoroaryl is one in which one or more hydrogen in aryl are replaced with fluorine.

In the present specification, when polymer has a plural type of repeating units, these repeating units copolymerize. This copolymerization can be alternating copolymerization, random copolymerization, block copolymerization, graft copolymerization, or a mixture of any of these.

In the present specification, “Wo” represents mass % and “ratio” represents ratio by mass.

In the present specification, Celsius is used as the temperature unit. For example, 20 degrees means 20 degrees Celsius.

### <Negative Type Photosensitive Composition>

The negative type photosensitive composition according to the present invention (hereinafter sometimes referred to as the composition) comprises (I) a polysiloxane, (II) an acrylic polymer, (III) a compound containing two or more (meth)acryloyloxy groups, (IV) a polymerization initiator, and (V) a solvent, wherein the component (III) is a combination of two or more kinds, and the content of the component (III) is 10.0 to 25.0 mass % based on the total mass of the component (I) and the component (II).

Hereinafter, each component contained in the composition according to the present invention is described in detail.

### (I) Polysiloxane

The polysiloxane used in the present invention is not particularly restricted on its structure and can be freely selected in accordance with the aimed applications. According to the number of the oxygen atoms connecting to a silicon atom, the structure of polysiloxane can be categorized into the following three skeletons, that is: silicone skeleton (in which two oxygen atoms connect to a silicon atom), silsesquioxane skeleton (in which three oxygen atoms connect to a silicon atom), and silica skeleton (in which four oxygen atoms connect to a silicon atom). In the present invention, the polysiloxane may have any of those skeletons. Further, the structure of the polysiloxane molecular can be a combination of two or more of them.

The polysiloxane used in the present invention preferably comprises a repeating unit represented by the formula (Ia):

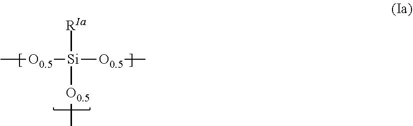

wherein,
R^{Ia} represents hydrogen, a C₁₋₃₀, preferably C₁₋₁₀, linear, branched or cyclic, saturated or unsaturated, aliphatic hydrocarbon group or aromatic hydrocarbon group, the aliphatic hydrocarbon group and the aromatic hydrocarbon group are each unsubstituted or substituted with fluorine, hydroxy or a C₁₋₈ alkoxy, and methylene (—CH₂—) in the aliphatic hydrocarbon group and the aromatic hydrocarbon group is not replaced or replaced with oxy, imino, or carbonyl, provided that R^{Ia} is neither hydroxy nor alkoxy.

The above-described methylene includes terminal methyl as well.

Further, the above “substituted with fluorine, hydroxy or a C₁₋₈ alkoxy” means that a hydrogen atom directly bonded to a carbon atom in the aliphatic hydrocarbon group or the aromatic hydrocarbon group is replaced with fluorine, hydroxy or a C₁₋₈ alkoxy. In the present specification, the same applies to other similar descriptions.

In the repeating unit represented by the formula (Ia), examples of R^{Ia} include (i) alkyl, such as methyl, ethyl, propyl, butyl, pentyl, hexyl, heptyl, octyl and decyl, (ii) aryl, such as phenyl, tolyl and benzyl, (iii) fluoroalkyl, such as trifluoromethyl, 2,2,2-trifluoroethyl, 3,3,3-trifluoropropyl, (iv) fluoroaryl, (v) cycloalkyl, such as cyclohexyl, (vi) a nitrogen-containing group having an amino or imide structure, such as isocyanate and amino, and (vii) an oxygen-containing group having an epoxy structure such as glycidyl, or an acryloyl structure or a methacryloyl structure. Preferred are methyl, ethyl, propyl, butyl, pentyl, hexyl, and phenyl. It is preferable that R^{Ia} is methyl because the raw material is easily available, the film hardness after curing is high, and the chemical resistance is high. Further, it is preferable that R^{Ia} is phenyl because the solubility of the polysiloxane in the solvent is increased and the cured film is less likely to crack.

The polysiloxane used in the present invention can further comprise a repeating unit represented by the formula (Ib):

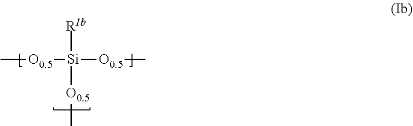

wherein,
R^{Ib} is a group obtained by removing two or more hydrogen atoms from a nitrogen and/or oxygen-containing cycloaliphatic hydrocarbon compound having an amino group, an imino group and/or a carbonyl group.

In the formula (Ib), R^{Ib} is preferably a group obtained by removing two or more hydrogen atoms, preferably two or three hydrogen atoms, from preferably a nitrogen-containing aliphatic hydrocarbon ring having an imino group and/or a carbonyl group, more preferably a 5-membered or 6-membered ring containing nitrogen as a member. For example, groups obtained by removing two or three hydrogen atoms from piperidine, pyrrolidine or isocyanurate are included. R^{Ib} connects Si each other included in plural repeating units.

The polysiloxane used in the present invention can further comprise a repeating unit represented by the following formula (Ic).

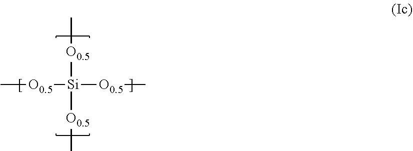

When the mixing ratio of the repeating units represented by the formulas (Ib) and (Ic) is high, photosensitivity of the composition decreases, compatibility with solvents and additives decreases, and the film stress increases, so that cracks sometimes easily generate. Therefore, it is preferably 40 mol % or less, and more preferably 20 mol % or less, based on the total number of the repeating units of polysiloxane.

The polysiloxane used in the present invention can further comprise a repeating unit represented by the formula (Id):

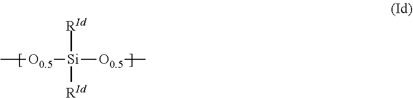

wherein,
R^{Id} each independently represents hydrogen, a C₁₋₃₀, preferably C₁₋₁₀, linear, branched or cyclic, saturated or unsaturated, aliphatic hydrocarbon group or aromatic hydrocarbon group,
the aliphatic hydrocarbon group and the aromatic hydrocarbon group are each unsubstituted or substituted with fluorine, hydroxy or a C₁₋₈ alkoxy, and methylene in the aliphatic hydrocarbon group and the aromatic hydrocarbon group is not replaced or replaced with oxy, imino, or carbonyl, provided that R^{Id} is neither hydroxy nor alkoxy.

In the repeating unit represented by the formula (Id), examples of R^{Id} include (i) alkyl, such as methyl, ethyl, propyl, butyl, pentyl, hexyl, heptyl, octyl and decyl, (ii) aryl, such as phenyl, tolyl and benzyl, (iii) fluoroalkyl, such as trifluoromethyl, 2,2,2-trifluoroethyl, 3,3,3-trifluoropropyl, (iv) fluoroaryl, (v) cycloalkyl, such as cyclohexyl, (vi) a nitrogen-containing group having an amino or imide structure, such as isocyanate and amino, and (vii) an oxygen-containing group having an epoxy structure such as glycidyl, or an acryloyl structure or a methacryloyl structure. Preferred are methyl, ethyl, propyl, butyl, pentyl, hexyl, and phenyl. It is preferable that R^{Id} is methyl because the raw material is easily available, the film hardness after curing is high, and the chemical resistance is high. Further, it is preferable that R^{Id} is phenyl because the solubility of the polysiloxane in the solvent is increased and the cured film is less likely to crack.

Through having the repeating unit represented by the above formula (Id), the polysiloxane used in the present invention can have a partially linear structure. However, since the heat resistance is reduced, it is preferable that the linear structure portion is small. In particular, the amount of the repeating unit represented by the formula (Id) is preferably 30 mol % or less, more preferably 5 mol % or less, based on the total number of the polysiloxane repeating units. It is also one preferable embodiment of the present invention that no repeating unit represented by the formula (Id) is contained (0 mol %).

The polysiloxane used in the present invention can comprise two or more types of repeating units. For example, it can contain three types of repeating units, which have repeating units represented by the formula (Ia) in which R^{Ia} is methyl and phenyl and a repeating unit represented by the formula (Ic).

The polysiloxane used in the present invention preferably has silanol. Silanol means OH group bonded directly to Si back bone of polysiloxane. In the polysiloxane comprising repeating units such as formulae (Ia) to (Id), hydroxy bonds directly to a silicon atom. That is, silanol is formed by bonding —O_{0.5}H to —O_{0.5}— of the above formulae (Ia) to (Id). The content of silanol in polysiloxane varies depending on the synthesis conditions, for example monomer mixing ratio and kinds of reaction catalyst.

The mass average molecular weight of the polysiloxane used in the present invention is not particularly limited. However, the higher the molecular weight is, the more the coating properties tend to be improved. On the other hand, the lower the molecular weight is, the less the synthesis conditions are limited and the easier the synthesis is, and it is difficult to synthesize polysiloxane having a very high molecular weight. For these reasons, the mass average molecular weight of polysiloxane is usually 500 to 25,000, and preferably 1,000 to 20,000 in view of the solubility in an organic solvent. The mass average molecular weight is a mass average molecular weight in terms of polystyrene, which can be measured by gel permeation chromatography based on polystyrene.

The synthesis method of the polysiloxane used in the present invention is not particularly limited. For example, it can be synthesized according to the method disclosed in JP 6639724 B.

The content of the polysiloxane (I) is preferably 2.0 to 15.0 mass %, and more preferably 3.0 to 12.0 mass %, based on the total mass of the composition. The mixing ratio of the polysiloxane (I) and the acrylic polymer (II) is not particularly limited. When the coating film is thickened, it is preferable that the mixing ratio of the acrylic polymer is high. On the other hand, when the composition is applied to high temperature process, it is preferable that the mixing ratio of the polysiloxane is high, in view of transparency and chemical resistance after curing. For these reasons, the content of the polysiloxane (I) is preferably 8.0 to 35.0 mass % and more preferably 10.0 to 30.0 mass %, based on the total mass of the polysiloxane (I) and the acrylic polymer (II).

### (II) Acrylic Polymer

The acrylic polymer used in the present invention can be selected from commonly used acrylic polymer, such as polyacrylic acid, polymethacrylic acid, polyalkyl acrylate, polyalkyl methacrylate. The acrylic polymer used in the present invention preferably comprises a repeating unit containing an acryloyl group. It is also preferable that the acrylic polymer further comprises a repeating unit containing a carboxy group and/or a repeating unit containing an alkoxysilyl group.

Although the repeating unit containing a carboxy group is not particularly limited as long as it is a repeating unit containing a carboxy group at its side chain, a repeating unit derived from an unsaturated carboxylic acid, an unsaturated carboxylic anhydride or a mixture thereof is preferable.

Although the repeating unit containing an alkoxysilyl group can be a repeating unit containing an alkoxysilyl group at its side chain, it is preferably a repeating unit derived from a monomer represented by the following formula (B):

X^{B}—(CH₂)ₐ—Si(OR^{B})_{b}(CH₃)_{3-b} (B)

wherein,
X^{B} is a vinyl group, a styryl group or a (meth)acryloyloxy group, and RB is a methyl group or an ethyl group, a is an integer of 0 to 3, and b is an integer of 1 to 3.

Further, it is preferable that the above-described polymer contains a repeating unit containing a hydroxy group derived from a hydroxy group-containing unsaturated monomer.

The mass average molecular weight of the acrylic polymer used in the present invention is not particularly limited, and is preferably 1,000 to 40,000, more preferably 2,000 to 30,000. The mass average molecular weight is a mass average molecular weight in terms of polystyrene according to gel permeation chromatography.

The content of the acrylic polymer (II) is preferably 18.0 to 35.0 mass %, and more preferably 20.0 to 32.0 mass %, based on the total mass of the composition.

The content of the acrylic polymer (II) is preferably 65.0 to 92.0 mass %, and more preferably 70.0 to 90.0 mass %, based on the total mass of the polysiloxane (I) and the acrylic polymer (II).

### (III) Compound Containing Two or More (Meth)Acryloyloxy Groups

The composition according to the present invention comprises a compound containing two or more (meth)acryloyloxy groups (hereinafter sometimes referred to as (meth)acryloyloxy group-containing compound). The (meth)acryloyloxy group is a general term for the acryloyloxy group and the methacryloyloxy group. This compound is a compound that can form a crosslinked structure by reacting with the polysiloxane (I), acrylic polymer (II) and the like. In order to form a crosslinked structure, a compound containing two or more (meth)acryloyloxy groups, which are reactive groups, is needed. In order to form a higher-order crosslinked structure, it preferably contains three or more (meth)acryloyloxy groups.

As such a compound containing two or more (meth)acryloyloxy groups, esters obtained by reacting (α) a polyol compound having two or more hydroxy groups with (β) two or more (meth)acrylic acids are preferably used. As the polyol compound (α), compounds having, as a basic skeleton, a saturated or unsaturated aliphatic hydrocarbon, aromatic hydrocarbon, heterocyclic hydrocarbon, primary, secondary or tertiary amine, ether or the like, and having, as substituents, two or more hydroxy groups are included. The polyol compound can contain other substituents, for example, a carboxy group, a carbonyl group, an amino group, an ether bond, a thiol group, a thioether bond, and the like, as long as the effects of the present invention are not impaired.

Preferred polyol compounds include alkyl polyols, aryl polyols, polyalkanolamines, cyanuric acid, and dipentaerythritol. When the polyol compound (α) has three or more hydroxy groups, it is not necessary that all the hydroxy groups have reacted with (meth)acrylic acid, and they can be partially esterified. This means that the esters can have unreacted hydroxy group(s).

As such esters, tris(2-acryloxyethyl)isocyanurate, bis(2-acryloxyethyl)isocyanurate, dipentaerythritol hexa(meth)acrylate, tripentaerythritol octa(meth) acrylate, pentaerythritol tetra(meth)acrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecane dimethanol diacrylate, 1,9-nonanediol diacrylate, 1,6-hexanediol diacrylate, 1,10-decanediol diacrylate are included.

The composition according to the present invention comprises a combination of two or more kinds of the (meth)acryloyloxy group-containing compounds, and preferably a combination of three or more kinds of the (meth)acryloyloxy group-containing compounds. In one preferred embodiment of the present invention, the composition according to the present invention comprises a combination of three kinds of the (meth)acryloyloxy group-containing compounds.

Without wishing to be bound by theory, it is considered that the combination of the (meth)acryloyloxy group-containing compounds with different glass transition temperatures can suppress rapid thermal reflow in the post baking process, which can lead to form a certain taper angle.

Preferably, at least one of two or more kinds of the (meth)acryloyloxy group-containing compounds is the compound containing three or more (meth)acryloyloxy groups. More preferably, at least one is the compound containing three or more (preferably three) (meth)acryloyloxy groups, and at least one is the compound containing two (meth)acryloyloxy groups. Further preferably, in order to make the pattern surface smoother, the component (III) is a combination of one kind of the compound containing three (meth)acryloyloxy groups and two kinds of the compounds containing two (meth)acryloyloxy groups.

In the composition according to the present invention, the content of the compounds containing three or more (meth)acryloyloxy groups is preferably 20.0 to 50.0 mass %, and more preferably 30.0 to 40.0 mass %, based on the total mass of the component (III).

In another embodiment of the present invention, in order to improve alkali solubility during development and heat resistance of the cured film, the component (III) preferably comprises the compound having an isocyanurate structure. In particular, such compounds include tris(2-acryloyloxyethyl)isocyanurate, bis(2-acryloyloxyethyl)isocyanurate, tris(3-acryloyloxypropyl)isocyanurate, bis(3-acryloyloxypropyl)isocyanurate, tris(4-acryloyloxybutyl)isocyanurate, bis(4-acryloyloxybutyl)isocyanurate, and preferably tris(2-acryloyloxyethyl)isocyanurate.

In the composition according to the present invention, the content of the compound having an isocyanurate structure is preferably 10.0 to 50.0 mass %, and more preferably 10.0 to 40.0 mass %, based on the total mass of the component (III).

From the viewpoint of the reactivity, the molecular weight of the compound containing two or more (meth)acryloyloxy groups is preferably 200 to 2,000, and more preferably 200 to 1,500.

Although the content of the component (III) is adjusted according to the type of the polymer or the (meth)acryloyloxy group-containing compound to be used, it is preferably 10.0 to 25.0 mass %, and more preferably 10.0 to 20.0 mass %, based on the total mass of the polysiloxane (I) and the acrylic polymer (II) from the viewpoint of compatibility with polymers.

### (IV) Polymerization Initiator

The composition according to the present invention comprises a polymerization initiator. The polymerization initiator includes a polymerization initiator that generates an acid, a base or a radical by radiation, and a polymerization initiator that generates an acid, a base or a radical by heat. In the present invention, the former is preferable and the photo radical generator is more preferable, in terms of process shortening and cost since the reaction is initiated immediately after the irradiation of radiation and the reheating process performed after the irradiation of radiation and before the development process can be eliminated.

The photo radical generator can improve the resolution by strengthening the shaped pattern or increasing the contrast of development. The photo radical generator used in the present invention is a photo radical generator that emits a radical when irradiated with radiation. Examples of the radiation include visible light, ultraviolet light, infrared light, X-ray, electron beam, α-ray, and γ-ray.

The content of the photo radical generator is preferably 0.001 to 30 mass %, and more preferably 0.01 to 10 mass %, based on the total mass of the component (I) and the component (II), though the optimal amount thereof depends on the type and amount of active substance generated by decomposition of the photo radical generator, the required photosensitivity, and the required dissolution contrast between the exposed area and unexposed area. If the content is less than 0.001 mass %, the dissolution contrast between the exposed area and unexposed portion is too low, and the addition effect is not sometimes exhibited. On the other hand, when the content of the photo radical generator is more than 30 mass %, cracks are generated in the coated film and colorless transparency of the coated film sometimes degrades, because coloring becomes remarkable due to decomposition of the photo radical generator. When the content becomes large, thermal decomposition may cause deterioration of the electrical insulation of the cured product and release of gas, which sometimes becomes a problem in subsequent processes. Further, the resistance of the coated film to a photoresist stripper containing monoethanolamine or the like as a main component sometimes deteriorates.

Examples of the photo radical generator include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferred, and 2,2-dimethoxy-1,2-diphenylethan-1-one, 1-hydroxy-cyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)-benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)-phenyl]-1-butanone, 2,4,6-trimethylbenzoyldiphenyl-phosphine oxide, bis(2,4,6-trimethylbenzoyl)-phenylphosphine oxide, 1,2-octanedione-1-[4-(phenylthio)-2-(O-benzoyloxime)], 1-[9-ethyl-6-(2-methylbenzoyl)-9H-carbazol-3-yl]ethanone-1-(O-acetyloxime) are included.

### (IV) Solvent

The composition according to the present invention comprises a solvent. The solvent is not particularly limited as long as it can uniformly dissolve or disperse each component. Examples of the solvent that can be used in the present invention include ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether and propylene glycol monoethyl ether; propylene glycol alkyl ether acetates such as propylene glycol monomethyl ether acetate (PGMEA), propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate, methyl 3-methoxypropionate; and cyclic esters, such as γ-butyrolactone, and the like. Among them, it is preferable to use propylene glycol alkyl ether acetates or esters from the viewpoints of availability easiness, handling easiness and solubility of the polymers.

The solvent content of the composition according to the present invention can be freely adjusted according to the method for applying the composition, and the like. For example, when the composition is applied by spray coating, it is also possible to make the proportion of the solvent in the composition be 90 mass % or more. In the case of slit coating, which is used for coating a large substrate, the solvent content is usually 60 mass % or more, and preferably 70 mass % or more. The properties of the composition of the present invention does not vary largely with the amount of solvent.

Although the composition according to the present invention essentially includes the above-described (I) to (V), further compounds can be optionally included. The materials that can be included are as described below. The content of the components other than (I) to (V) in the entire composition is preferably 30 mass % or less, and more preferably 20 mass % or less, based on the total mass of the composition.

The composition according to the present invention can optionally comprise other additives. As such additives, a developer dissolution accelerator, a scum remover, an adhesion enhancer, a polymerization inhibitor, an antifoaming agent, a surfactant, and a sensitizer are included.

The developer dissolution accelerator or scum remover has a function of adjusting the solubility of the formed coated film in the developer and preventing scum from remaining on the substrate after development. As such an additive, crown ether can be used. The crown ether having the simplest structure is represented by the general formula (—CH₂—CH₂—O—)ₙ. Preferred in the present invention are those in which n is 4 to 7. When x is set to be the total number of atoms constituting the ring and y is set to be the number of oxygen atoms contained therein, the crown ether is sometimes called x-crown-y-ethers. In the present invention, preferred is selected from the group consisting of crown ethers, wherein x=12, 15, 18 or 21, and y=x/3, and their benzo condensates and cyclohexyl condensates. Exemplified embodiments of more preferred crown ethers include 21-crown-7-ether, 18-crown-6-ether, 15-crown-5-ether, 12-crown-4-ether, dibenzo-21-crown-7-ether, dibenzo-18-crown-6-ether, dibenzo-15-crown-5-ether, dibenzo-12-crown-4-ether, dicyclohexyl-21-crown-7-ether, dicyclohexyl-18-crown-6-ether, dicyclo-hexyl-15-crown-5-ether, and dicyclohexyl-12-crown-4-ether. In the present invention, among them, most preferred is selected from 18-crown-6-ether and 15-crown-5-ether. The content thereof is preferably 0.05 to 15 mass %, and more preferably 0.1 to 10 mass %, based on the total mass of the component (I) and the component (II).

The adhesion enhancer has an effect of preventing a pattern from peeling off due to stress applied after baking when a cured film is formed using the composition according to the present invention. As the adhesion enhancer, imidazoles, silane coupling agents, and the like are preferred. Among imidazoles, 2-hydroxybenzimidazole, 2-hydroxyethylbenzimidazole, benzimidazole, 2-hydroxyimidazole, imidazole, 2-mercaptoimidazole and 2-aminoimidazole are preferable, and 2-hydroxybenzimidazole, benzimidazole, 2-hydroxyimidazole and imidazole are particularly preferably used.

As the polymerization inhibitor, an ultraviolet absorber as well as nitrone, nitroxide radical, hydroquinone, catechol, phenothiazine, phenoxazine, hindered amine and derivatives thereof can be added. Among them, methylhydroquinone, catechol, 4-t-butylcatechol, 3-methoxycatechol, phenothiazine, chlorpromazine, phenoxazine, TINUVIN 144, 292 and 5100 (BASF) as the hindered amine, and TINUVIN 326, 328, 384-2, 400 and 477 (BASF) as the ultraviolet absorber are preferred. These can be used alone or in combination of two or more, and the content thereof is preferably 0.01 to 20 mass % based on the total mass of the component (I) and the component (II).

As the antifoaming agent, alcohols (C₁₋₁₈), higher fatty acids such as oleic acid and stearic acid, higher fatty acid esters such as glycerin monolaurate, polyethers such as polyethylene glycols (PEG) (Mn: 200 to 10,000) and polypropylene glycols (PPG) (Mn: 200 to 10,000), silicone compounds such as dimethyl silicone oil, alkyl-modified silicone oil and fluorosilicone oil, and organosiloxane-based surfactants described in detail below are included. These can be used alone or in combination of a plurality of these, and the content thereof is preferably 0.1 to 3 mass % based on the total mass of the component (I) and the component (II).

The surfactant is added for the purpose of improving coating properties, developability, and the like. Examples of the surfactant that can be used in the present invention include nonionic surfactants, anionic surfactants, and amphoteric surfactants.

Examples of the nonionic surfactant include, polyoxyethylene alkyl ethers, such as polyoxyethylene lauryl ether, polyoxyethylene oleyl ether and polyoxyethylene cetyl ether; polyoxyethylene fatty acid diester; polyoxyethylene fatty acid monoester; polyoxyethylene polyoxypropylene block polymer; acetylene alcohol; acetylene glycol; polyethoxylate of acetylene alcohol; acetylene glycol derivatives, such as polyethoxylate of acetylene glycol; fluorine-containing surfactants, such as Fluorad (trade name, 3M Japan Limited), Megafac (trade name, DIC Corporation), Surflon (trade name, AGC Inc.); or organosiloxane surfactants, such as KP341 (trade name, Shin-Etsu Chemical Co., Ltd.). Examples of the above-described acetylene glycol include 3-methyl-1-butyne-3-ol, 3-methyl-1-pentyn-3-ol, 3,6-dimethyl-4-octyne-3,6-diol, 2,4,7,9-tetramethyl-5-decyne-4,7-diol, 3,5-dimethyl-1-hexyne-3-ol, 2,5-di-methyl-3-hexyne-2,5-diol, 2,5-di-methyl-2,5-hexanediol.

Examples of the anionic surfactant include ammonium salt or organic amine salt of alkyl diphenyl ether disulfonic acid, ammonium salt or organic amine salt of alkyl diphenyl ether sulfonic acid, ammonium salt or organic amine salt of alkyl benzene sulfonic acid, ammonium salt or organic amine salt of polyoxyethylene alkyl ether sulfuric acid, ammonium salt or organic amine salt of alkyl sulfuric acid.

Examples of the amphoteric surfactant include 2-alkyl-N-carboxymethyl-N-hydroxyethyl imidazolium betaine, lauric acid amide propyl hydroxysulfone betaine.

These surfactants can be used alone or as a mixture of two or more types, and the content thereof is preferably 0.005 to 1 mass %, more preferably 0.01 to 0.5 mass %, based on the total mass of the composition.

Examples of the sensitizer include coumarin, ketocoumarin and their derivatives, thiopyrylium salts, acetophenones. By the addition of the sensitizing dye, patterning using an inexpensive light source such as a high-pressure mercury lamp (360 to 430 nm) becomes possible. The content thereof is preferably 0.05 to 15 mass %, and more preferably 0.1 to 10 mass %, based on the total mass of the component (I) and the component (II).

### <Method for Manufacturing a Pattern>

The method for manufacturing a pattern according to the present invention comprises applying the composition according to the present invention above a substrate, exposing, and developing. The method for manufacturing a pattern is described in process order as follows.

### (1) Application Process

First, the above-described composition is applied above a substrate. In the present invention, the “above a substrate” includes the case where the composition is applied directly on a substrate and the case where the composition is applied on a substrate via one or more intermediate layer. Formation of the coating film of the composition in the present invention can be carried out by any method conventionally known as a method for applying a photosensitive composition. It can be freely selected from dip coating, roll coating, bar coating, brush coating, spray coating, doctor coating, flow coating, spin coating, slit coating, and the like. As the substrate on which the composition is applied, a suitable substrate such as a silicon substrate, a glass substrate, a resin film, and the like can be used. Various semiconductor devices and the like can be formed on these substrates as needed. When the substrate is a film, gravure coating can also be utilized. If desired, a drying process can be additionally provided after applying the film. Further, if necessary, the applying process can be repeated once or twice or more to make the film thickness of the coating film to be formed as desired.

(2) Pre-baking process

After forming the coating film of the composition by applying the composition, it is preferable to carry out pre-baking (heat treatment) of the coating film in order to dry the coating film and reduce the residual amount of the solvent in the coating film. The pre-baking process can be carried out at a temperature of generally 50 to 150° C., preferably 90 to 120° C., in the case of a hot plate, for 10 to 300 seconds, preferably 30 to 120 seconds and in the case of a clean oven, for 1 to 30 minutes.

### (3) Exposure Process

After forming a coating film, the coating film surface is then irradiated with light. As the light source to be used for the light irradiation, any one conventionally used for a pattern forming method can be used. As such a light source, a high-pressure mercury lamp, a low-pressure mercury lamp, a lamp such as metal halide and xenon, a laser diode, an LED, and the like can be included. As the irradiation light, ultraviolet ray such as g-line, h-line and i-line is usually used. Except ultrafine processing for semiconductors or the like, it is general to use light of 360 to 430 nm (high-pressure mercury lamp) for patterning of several μm to several dozen μm. Above all, in the case of liquid crystal display devices, light of 430 nm is often used. In such a case, as described above, it is advantageous to combine a sensitizing dye with the composition according to the present invention. The energy of the irradiation light is generally 5 to 2,000 mJ/cm², preferably 10 to 1,000 mJ/cm², although it depends on the light source and the film thickness of the coating film. If the irradiation light energy is lower than 5 mJ/cm², sufficient resolution cannot be obtained in some cases. On the other hand, when the irradiation light energy is higher than 2,000 mJ/cm², the exposure becomes excess and halation sometimes occurs.

In order to irradiate light in a pattern shape, a general photomask can be used. Such a photomask can be freely selected from well-known ones. The environment at the time of irradiation is not particularly limited and can generally be set as an ambient atmosphere (in the air) or nitrogen atmosphere. Further, in the case of forming a film on the entire surface of the substrate, light irradiation can be performed over the entire surface of the substrate. In the present invention, the pattern film also includes such a case where a film is formed on the entire surface of the substrate.

### (4) Post Exposure Baking Process

After the exposure, to promote the reaction between the polymer in the film by the polymerization initiator, post exposure baking can be performed, as necessary. Different from the heating process (6) to be described later, this heating treatment is performed not to completely cure the coating film but to leave only a desired pattern on the substrate after development and to make other areas capable of being removed by development. Therefore, it is not essential in the present invention.

When the post exposure baking is performed, a hot plate, an oven, a furnace, and the like can be used. The heating temperature should not be excessively high because it is not desirable for the acid, base or radical in the exposed area, which is generated by light irradiation, to diffuse to the unexposed area. From such a viewpoint, the range of the heating temperature after exposure is preferably 40 to 150° C., and more preferably 60 to 120° C. Stepwise heating can be applied as needed to control the curing rate of the composition. Further, the atmosphere during the heating is not particularly limited and can be selected from in an inert gas such as nitrogen, under a vacuum, under a reduced pressure, in an oxygen gas, and the like, for the purpose of controlling the curing rate of the composition. Further, the heating time is preferably above a certain level in order to maintain higher the uniformity of temperature history in the wafer surface and is preferably not excessively long in order to suppress diffusion of the generated acid, base or radical. From such a viewpoint, the heating time is preferably 20 seconds to 500 seconds, and more preferably 40 seconds to 300 seconds.

### (5) Developing Process

After post-exposure baking is optionally performed after exposure, the coating film is developed. As the developer to be used at the time of development, any developer conventionally used for developing a photosensitive composition can be used. Preferable examples of the developer include an alkali developer which is an aqueous solution of an alkaline compound such as tetraalkylammonium hydroxide, choline, alkali metal hydroxide, alkali metal metasilicate (hydrate), alkali metal phosphate (hydrate), ammonia, alkylamine, alkanolamine and heterocyclic amine, and a particularly preferable alkali developer is tetramethylammonium hydroxide (TMAH) aqueous solution, a potassium hydroxide aqueous solution, or a sodium hydroxide aqueous solution. In this alkali developer, a water-soluble organic solvent such as methanol and ethanol, or a surfactant can be further contained, if necessary. The developing method can also be freely selected from conventionally known methods. Specifically, methods such as dipping in a developer (dip), paddle, shower, slit, cap coat, spray, and the like can be included. After the development with a developer, by which a pattern can be obtained, it is preferable that rinsing with water is carried out.

### (6) Post Baking Process

After development, the obtained pattern film is cured by heating. As the heating apparatus used for the heating process, the same one as used for the above-described post-exposure baking can be used. The heating temperature in the heating process is not particularly limited as long as it is a temperature at which curing of the coating film can be performed and can be freely determined. However, if the silanol group of the polysiloxane remains, the chemical resistance of the cured film sometimes becomes insufficient, or dielectric constant of the cured film sometimes becomes higher. From such a viewpoint, a relatively high temperature is generally selected as the heating temperature. In order to keep the remaining film ratio after curing high, the curing temperature is more preferably 350° C. or lower, and particularly preferably 250° C. or lower. On the other hand, in order to accelerate the curing reaction and obtain a sufficiently cured film, the curing temperature is preferably 70° C. or higher, more preferably 80° C. or higher, and particularly preferably 90° C. or higher. The heating time is not particularly limited and is generally 10 minutes to 24 hours, and preferably 30 minutes to 3 hours. In addition, this heating time is a time from when the temperature of the pattern film reaches a desired heating temperature. Usually, it takes about several minutes to several hours for the pattern film to reach a desired temperature from the temperature before heating.

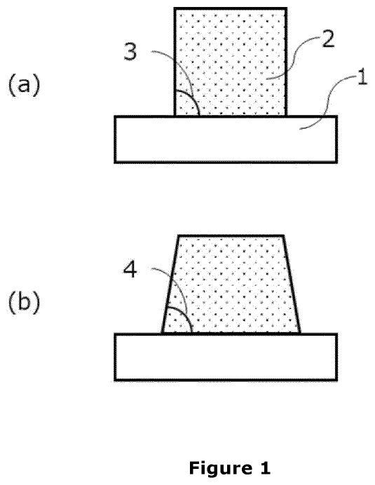

FIG. 1 is a conceptual diagram in which pattern 2 is formed on substrate 1. In the present invention, a pattern formed after developing process is typically rectangular. The angle between sidewall of the pattern and the substrate is referred to as taper angle 3. Cross section of the pattern after developing is typically rectangular as shown in FIG. 1 (a) (taper angle=90°). When the pattern is heated, the coating film tends to soften temporarily and change its cross-sectional shape from rectangular to trapezoidal. Thus, inclination angle of pattern sidewall, or taper angle, tends to decrease by heating, and bottom width of the pattern cross section, or line width, tends to increase. FIG. 1 (b) is trapezoidal, and its taper angle 4 is reduced compared to FIG. 1 (a).

When the composition according to the present invention is used, the shape after developing is close to rectangular, and then taper angle can be changed to 15 to 80°, preferably 40 to 80°, by heating. Even if further heated, the shape can be maintained without further reducing the taper angle.

Taper angle is defined at a portion where the substrate and the pattern contact each other, and can be measured by observing vertical cross-sectional shape of the pattern with scanning electron microscope (SEM).

The cured film thus obtained can achieve excellent transparency. When the film thickness is 2 μm, the transmittance of light having a wavelength of 400 nm is preferably 90% or more and more preferably 95% or more.

The method for manufacturing a device according to the present invention comprises the above-described method for manufacturing a pattern. The pattern manufactured by using the composition according to the present invention has high transmittance and a certain taper angle, and thus it can be suitably used for a partition wall which divide into pixels in display devices. Since the pattern according to the present invention can be made thicker, it can be suitably used for micro LEDs, quantum dot displays, and organic electroluminescence devices that require a thicker partition wall material.

The present invention is explained more particularly below with reference to Examples and Comparative Examples, but the present invention is not limited by these Examples and Comparative Examples at all.

Gel permeation chromatography (GPC) is measured using two columns of HLC-8220 GPC type high-speed GPC system (trade name, manufactured by Tosoh Corporation) and Super Multipore HZ—N type GPC column (trade name, manufactured by Tosoh Corporation). The measurement is performed using monodisperse polystyrene as a standard sample and tetrahydrofuran as an eluent, under the analytical conditions of a flow rate of 0.6 nil/min and a column temperature of 40° C.

### Synthesis Example 1: Polysiloxane A

In a 2 L flask equipped with a stirrer, a thermometer and a condenser, 49.0 g of a 25 mass % TMAH aqueous solution, 600 ml of isopropyl alcohol (IPA), and 4.0 g of water are charged, and then in a dropping funnel, a mixed solution of 68.0 g of methyltrimethoxysilane, 79.2 g of phenyltrimethoxysilane, and 15.2 g of tetramethoxysilane is prepared. The mixed solution is added dropwise at 40° C., stirred at the same temperature for 2 hours, and neutralized by adding a 10 mass % aqueous solution of HCl. 400 ml of toluene and 600 ml of water are added to the neutralized solution to separate into two layers, and the aqueous layer is removed. Further, the resulting product is rinsed three times with 300 ml of water, the obtained organic layer is concentrated under reduced pressure to remove the solvent, and PGMEA is added to the concentrate to adjust the solid content to be 35 mass %, thereby obtaining Polysiloxane A solution. Mass average molecular weight (Mw) of the obtained Polysiloxane A is 1,700.

### Synthesis Example 2: Acrylic Polymer A

In a 2 L flask equipped with a stirrer, a thermometer, a condenser and a nitrogen gas introducing pipe, normal butanol and PGMEA solvent are charged, and under a nitrogen gas atmosphere, the temperature is raised to an appropriate temperature, while referring to the 10-hour half-life temperature of the initiator. Separately from that, a mixture liquid of acrylic acid, γ-methacryloxypropyltrimethoxysilane, 2-hydroxyethyl methacrylate and methyl methacrylate at 10:20:20:50, azobisisobutyronitrile, and PGMEA is prepared, and the mixture liquid is dropped into the above-described solvent over 4 hours. Thereafter, the resulting product is reacted for 3 hours to obtain Acrylic polymer A. Mw of the obtained Acrylic polymer A is 8,700.

### Synthesis Example 3: Acrylic Polymer B

In a 1 L flask equipped with a stirrer, a thermometer, a condenser and a nitrogen gas introducing pipe, 16.4 g of azobisisobutyronitrile and 120 g of butanol are charged, and under a nitrogen gas atmosphere, the temperature is raised to an appropriate temperature, while referring to the 10-hour half-life temperature of the initiator. Separately from that, a mixture liquid of 5.16 g of methacrylic acid, 46.5 g of 3-methacryloxypropylmethyldimethoxysilane, 6.5 g of 2-hydroxyethyl methacrylate and 70.08 g of methyl methacrylate is prepared, and the mixture liquid is dropped into the above-described solvent over 4 hours. Thereafter, the resulting product is reacted for 3 hours to obtain Acrylic polymer B. Mw of the obtained Acrylic polymer B is 7,350.

### Example 1

To a solution containing 20 parts by mass of Polysiloxane A obtained in Synthesis Example 1, 40 parts by mass of Acrylic polymer A obtained in Synthesis Example 2, and 40 parts by mass of Acrylic polymer B obtained in Synthesis Example 3, 3 parts by mass of polymerization initiator A (“ADEKA ARKLS NCI-930”, ADEKA Corporation), 6 parts by mass of (meth)acryloyloxy group-containing compound A (1,10-decanediol diacrylate, “A-DOD-N”, Shin-Nakamura Chemical Co., Ltd.), 6 parts by mass of (meth)acryloyloxy group-containing compound B (tricyclodecane dimethanol diacrylate, “A-DCP”, Shin-Nakamura Chemical Co., Ltd.), 6 parts by mass of (meth)acryloyloxy group-containing compound C (tris-(2-acryloxyethyl)isocyanurate, “A-9300”, Shin-Nakamura Chemical Co., Ltd.), and 0.5 parts by mass of surfactant A (“KF-53”, Shin-Etsu Chemical Co., Ltd.) are added, and PGMEA is further added so that the solid content of the solution is 35 mass %, to obtain a composition of Example 1.

### Examples 2 to 5, Comparative Examples 1 to 6

Compositions of Examples 2 to 5 and Comparative Examples 1 to 6 are prepared in which each constitution is changed from Example 1 as shown in Table 1. The numerical values in the table indicate parts by mass.

TABLE 1

| | | | Examples | | | | | Comparative Examples | | | | | |
|---|---|---|---|---|---|---|---|---|---|---|---|---|---|
| | | | 1 | 2 | 3 | 4 | 5 | 1 | 2 | 3 | 4 | 5 | 6 |
| Constitution | (I) | Polysiloxane A | 20 | 20 | 20 | 10 | 30 | 20 | 20 | 20 | 20 | 20 | 20 |
| | (II) | Acrylic polymer A | 40 | 40 | 40 | 45 | 35 | 40 | 40 | 40 | 40 | 40 | 40 |
| | | Acrylic polymer B | 40 | 40 | 40 | 45 | 35 | 40 | 40 | 40 | 40 | 40 | 40 |
| | (III) | (meth)acryloyloxy group- | 6 | 4 | 10 | 6 | 10 | 2 | 10 | 9 | 18 | — | — |
| | | containing compound A | | | | | | | | | | | |
| | | (meth)acryloyloxy group- | 6 | 4 | — | 6 | — | 2 | 10 | 9 | — | 18 | — |
| | | containing compound B | | | | | | | | | | | |
| | | (meth)acryloyloxy group- | 6 | 4 | 6 | 6 | 6 | 2 | 10 | 9 | — | — | 18 |
| | | containing compound C | | | | | | | | | | | |
| | (IV) | Polymerization initiator A | 3 | 3 | 3 | 3 | 3 | 3 | 3 | 3 | 3 | 3 | 3 |
| | Surfactant A | | 0.5 | 0.5 | 0.5 | 0.5 | 0.5 | 0.5 | 0.5 | 0.5 | 0.5 | 0.5 | 0.5 |
| Evaluation | Before | Film thickness (μm) | 20 | 20 | 20 | 20 | 20 | 20 | 20 | 20 | 20 | 20 | 20 |
| | post- | | | | | | | | | | | | |
| | bake | Taper angle (°) | 90 | 90 | 90 | 90 | 90 | 90 | 90 | 90 | 90 | 90 | 90 |
| | After | pattern reflow property | A | A | A | A | A | D | C | B | D | D | D |
| | post- | Film thickness (μm) | 15 | 12 | 10 | 14 | 12 | — | 16 | 16 | — | — | — |
| | bake | Taper angle (°) | 60 | 30 | 20 | 50 | 50 | flow | 90 | 85 | flow | flow | flow |

| | | | | | | | | | | | |
|---|---|---|---|---|---|---|---|---|---|---|---|
| Transmittance (%) | 97 | 97 | 97 | 97 | 97 | 97 | 97 | 97 | 97 | 97 | 97 |
| Elastic modulus (Gpa) | 7.8 | 6 | 5.5 | 7.2 | 5.8 | 6.4 | 9.4 | 8.4 | 4.2 | 4.3 | 4.3 |

Each of the obtained compositions is applied on a silicon wafer by spin coating and heated on a hot plate at 100° C. for 90 seconds (pre-baking) to form a film. The wafer is exposed at 50 mJ/cm² through a mask using an i-line exposure machine, immersed in a 2.38 mass % TMAH aqueous solution for 60 seconds, and rinsed with pure water 30 seconds to dry. As a result, 50 μm contact hole (C/H) patterns are formed.

At this time, the cross section of the substrate is observed with SEM, and the film thickness and taper angle are measured. The obtained results are shown in Table 1.

The wafer on which the pattern is formed as described above is heated at 230° C. for 30 minutes on a hot plate (post-baking) to form a cured film.

Then, the cross section of the pattern is observed with SEM, and the film thickness and taper angle are measured. Further, pattern reflow property is evaluated based on the following criteria. The obtained results are shown in Table 1.

A: Reflow occurs due to post-baking, and taper angle is 15 to 80°.

B: Reflow occurs due to post-baking, and taper angle is more than 80°.

C: Reflow do not occur before and after post-baking. That is, the shape does not change.

D: Reflow occurs due to post-baking, and taper angle measurement is not possible.

When the above described cured films formed by using Examples 1 to 5 are further heated at 250° C. for 10 minutes in the air, the taper angle does not change.

### [Transmittance]

Each of the obtained compositions is coated on alkalo-free grass by spin coating and prebaked on a hot plate at 100° C. for 90 seconds. Then, flood exposure is performed with 50 mJ/cm 2 using an i-line exposure machine, immersed in 2.38 mass % TMAH aqueous solution for 60 seconds, and rinsed with pure water for 30 seconds. Then, it is heated at 200° C. for 1 hour to form a cured film. The thickness of the obtained cured film is adjusted to 2.0 μm. The obtained cured film is measured with UV absorption measuring instrument (U-4000) and the transmittance of light having a wavelength of 400 nm is determined. The obtained results are shown in Table 1.

[Elastic Modulus]

The elastic modulus of the obtained cured films is measured with indentation hardness tester “ENT-21” (ELIONIX INC.) The obtained results are shown in Table 1.

### EXPLANATION OF SYMBOLS

1. Substrate
2. Pattern
3. Taper angle
4. Taper angle

1.-10. (canceled)

11. A negative type photosensitive composition comprising:
(I) a polysiloxane,
(II) an acrylic polymer,
(III) a compound containing two or more (meth)acryloyloxy groups,
(IV) a polymerization initiator, and
(V) a solvent,
wherein the component (III) is a combination of two or more kinds, and
the content of the component (III) is 10.0 to 25.0 mass % based on the total mass of the component (I) and the component (II).

12. The composition according to claim 11, wherein the polysiloxane (I) comprises a repeating unit represented by the formula (Ia): 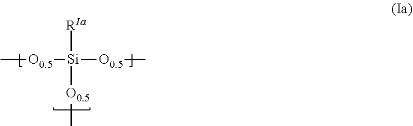
wherein,
R^{1a} represents hydrogen, a C₁₋₃₀ linear, branched or cyclic, saturated or unsaturated, aliphatic hydrocarbon group or aromatic hydrocarbon group,
the aliphatic hydrocarbon group and the aromatic hydrocarbon group are each unsubstituted or substituted with fluorine, hydroxy or a C₁₋₈ alkoxy, and
methylene (—CH₂—) in the aliphatic hydrocarbon group and the aromatic hydrocarbon group is not replaced or replaced with oxy, imino, or carbonyl, provided that R^{1a} is neither hydroxy nor alkoxy.

13. The composition according to claim 12, wherein the polysiloxane (I) further comprises a repeating unit represented by the formula (Ic)

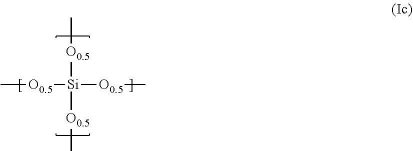

14. The composition according to claim 11, wherein the content of the polysiloxane (I) is 8.0 to 35.0 mass % based on the total mass of the polysiloxane (I) and the acrylic polymer (II).

15. The composition according to claim 11, wherein the component (III) is an ester compound obtained by reacting a polyol compound having two or more hydroxy groups with two or more (meth)acrylic acid.

16. The composition according to claim 11, wherein the component (III) is a combination of three or more kinds.

17. A method for manufacturing a pattern, comprising applying the composition according to claim 11 above a substrate, exposing, and developing.

18. The method according to claim 17, further comprising heating after developing.

19. The method according to claim 18, wherein the taper angle after heating is 15 to 80°.

20. A method for manufacturing a device comprising the method according to claim 17.
